(19) United States
(12) Patent Application Publication
(10) Pub. No.: US 2014/0202995 A1
(43) Pub. Date: Jul. 24, 2014

(54) PLASMA HEAT TREATMENT APPARATUS

(71) Applicant: HITACHI HIGH-TECHNOLOGIES CORPORATION, Tokyo (JP)

(72) Inventors: Masatoshi MIYAKE, Tokyo (JP); Ken'etsu YOKOGAWA, Tokyo (JP); Takashi UEMURA, Tokyo (JP); Hiromichi KAWASAKI, Tokyo (JP)

(73) Assignee: HITACHI HIGH-TECHNOLOGIES CORPORATION, Tokyo (JP)

(21) Appl. No.: 13/956,492

(22) Filed: Aug. 1, 2013

(30) Foreign Application Priority Data
Jan. 24, 2013 (JP) 2013-010802

(51) Int. Cl. H01L 21/324; H01J 37/32

(52) U.S. Cl. CPC H01L 21/324; H01J 37/32082
USPC 219/121.37

(57) ABSTRACT

A plasma heat treatment apparatus, provided for enabling a control of temperature distribution within electrode surfaces, without accompanying an increase of an electric power to be inputted therein, even in case when heating is made on a sample to be heated, having a large diameter thereof, with applying plasma, comprises a treatment chamber 100 for heat the sample 101 to be treated therein, a first electrode 102, which is disposed within the treatment chamber, a plate-shaped second electrode 103, which is disposed opposing to the first electrode 102, a radio-frequency power supply 111 for supplying radio-frequency electric power to the first electrode 102 or the second electrode 103, and a gas introducing means 113 for supplying a gas within the treatment chamber, wherein the first electrode 102 has an opening portion therein.

### CLAIM OF PRIORITY

The present application claims priority from Japanese Patent Application No. 2013-10802 filed on Jan. 24, 2013 the content of which is hereby incorporated by reference into this application.

### FIELD OF THE INVENTION

The present invention relates to a plasma heat treatment apparatus.

### BACKGROUND OF THE INVENTION

In recent years, as a material of substrates for power semiconductor devices is expected a new material, having a wide band gap, such as, silicon carbonate (SiC), or the like. The SiC, i.e., being the material having the wide band gap, has the physical characteristics, being superior to those of silicon (Si), i.e., such as, high breakdown voltage, a high saturate electron speed, and a high thermal conductivity, for example. Because of being a material of high breakdown voltage, SiC enables thin-sizing of an element and/or doping with high density, and therefore an element can be manufactured therefrom, to have high voltage durability and low resistance. Also, because of having a large band gap, it can suppress thermal excited electrons, and further because of being high in heat radiating power, due to the high thermal or heat conductivity, it enables a stable operation under high temperature. Accordingly, if achieving a SiC power semiconductor device, a great increase in efficiency and high performances can be expected, in various kinds of power/electric equipment, such as, for transmission/conversion of electric power, power apparatuses for use in industries and home appliances, and so on.

Processes for manufacturing various kinds of power devices with applying SiC as a substrate are almost similar to those when applying Si as the substrate. However, as the process largely differing from that can be listed up a heat treatment process. The representative one of the heat treatment processes is activation annealing after ion implantation of impurities, which is conducted for the purpose of controlling the conductivity of the substrate. In case of a Si device, the activation annealing is conducted under the condition of temperature 800 to 1,200° C. On the other hand, in case of the SiO device, temperature of 1,200 to 2,000° C. is necessary, due to the characteristics of that material.

As an annealing apparatus suitable for SiC is disclosed an apparatus, for heating a wafer with using atmospheric plasma, which is produced through high frequency radio-waves, in the following Japanese Patent Laid-Open No. 2012-216737.

### SUMMARY OF THE INVENTION

With such apparatus as described in the Japanese Patent Laying-Open No. 2012-216737, there can be expected an improvement of the heat efficiency, and improvement of heating responsibility, a low cost of expendables of furnace materials, etc., comparing to the conventional resistance heating furnace. Then, studies are made from a viewpoint of enlargement of diameter of a substrate (i.e., wafer) in the future, in relation to a heat treatment apparatus applying this atmosphere plasma therein. As a result thereof, it can be seen that there are following problems to be dissolved, from a viewpoint of temperature distribution within a wafer surface, if heating is made on the wafer with applying the atmosphere plasma therein.

The annealing apparatus disclosed in the Japanese Patent Laid-Open No. 2012-216737 conducts the heating by means of the plasma, which is produced between parallel plate electrodes through the high-frequency radio waves. In case where the plasma is distributed equally between the parallel plate electrodes and heat input into the electrodes is uniform, the temperature on outer peripheries of the electrodes is lowered under the temperature 1,200 to 2,000° C. necessary for the SiC activation, and this brings about distribution of temperature, i.e., the temperature is high at a central portion of the electrode. A reason of this, with the structure of the Japanese Patent Laying-Open No. 2012-216737, lies in that a heat radiation loss, being a dominant factor of the heat loss under the high temperature, comes to be large, in particular, on outer peripheries of those electrodes. In case of such temperature distribution, cracking caused due to thermal stress is generated in the electrodes and also variation of the activation is generated within the wafer surface; i.e., a possibility that sufficient device characteristics cannot be obtained. This tendency can be considered to become remarkable, in particular, when the wafer is enlarged in the diameter thereof. For the purpose of an improvement of the uniformity of the distribution of temperature within the wafer surface, it can be considered to apply electrodes, being sufficiently large with respect to the diameter of the wafer to be processed. However, in this case, because the radiation loss from the electrodes is increased up, there is generated a necessity of inputting a large electric power. On the other hand, for the purpose of controlling the distribution of temperature on the electrodes, it is effective to control the distribution of the plasma, i.e., the heat source; however, from a viewpoint of stability of the electric discharge, it is difficult or impossible to fluctuate the plasma distribution, extremely in large, by changing the process pressure or the distance between the electrodes.

An object of the present invention is to provide a plasma heat treatment apparatus for enabling a control of the distribution of temperature within electrode surfaces, without increasing the electric power to be inputted, even in case when heating is made on a sample to be processed, having a large diameter, with using the plasma.

According to the present invention, as an embodiment for accomplishing the object mentioned above, there is provided a plasma heat treatment apparatus, comprising:

a treatment chamber, which is configured to heat a sample to be treated therein;
a first electrode, which is disposed within the treatment chamber;
a plate-shaped second electrode, which is disposed opposing to the first electrode; and
a radio-frequency power supply, which is configured to supply radio-frequency electric power to the first electrode or the second electrode, wherein
the first electrode has an opening portion therein.

According to the present invention, it is possible to provide a plasma heat treatment apparatus for enabling a control on the distribution of temperature within electrode surfaces, without increasing the electric power to be inputted, even in case when heating is made on a sample to be processed, having a large diameter, with using the plasma.

### BRIEF DESCRIPTION OF THE DRAWINGS

Those and other objects, features and advantages of the present invention will become more readily apparent from the following detailed description when taken in conjunction with the accompanying drawings wherein:

FIG. 1 is a cross-section view for showing the fundamental configuration of a plasma heat treatment apparatus, according to an embodiment 1 of the present invention;

FIG. 2A is an upper plane view of the plasma heat treatment apparatus shown in FIG. 1, along A-A′ line thereof;

FIG. 2B is an upper plane view of the plasma heat treatment apparatus shown in FIG. 1, along B-B′ line thereof;

FIG. 3 is view for showing a result of comparison of temperature distribution, between that obtained on a lower electrode in the plasma heat treatment apparatus according to the embodiment 1 of the present invention (i.e., a ring-shaped upper electrode) and that obtained on a lower electrode in the conventional apparatus (i.e., a disc-shaped upper electrode);

FIG. 4 is a cross-section view for showing the fundamental configuration of a plasma heat treatment apparatus, according to an embodiment 2 of the present invention;

FIG. 5A is an upper plane view of the plasma heat treatment apparatus shown in FIG. 4, along A-A′ line thereof; FIG. 5B is an upper plane view of the plasma heat treatment apparatus shown in FIG. 4, along B-B′ line thereof; and

FIG. 6 is view for showing a result of comparison of temperature distribution, between that obtained on a lower electrode in the plasma heat treatment apparatus according to the embodiment 2 of the present invention (i.e., a double ring-shaped upper electrode) and that obtained on a lower electrode in the conventional apparatus (i.e., a disc-shaped upper electrode).

### DETAILED DESCRIPTION OF THE PREFERRED EMBODIMENTS

In a plasma heat treatment apparatus, because of utilization of the plasma as the heat source therein, it can be considered that the temperature distribution is generated on electrodes and also on a wafer, when bias or offset is generated within a region for producing the plasma. Then, the inventors conducted measurements on the distribution of temperature within electrode surfaces by means of a radiation thermometer and the distribution of sheet resistance within surfaces after treating a heating process on a silicon sample, in relation with if the offset is generated or not, in the temperature distribution. As a result thereof, the offset of the temperature distribution can be confirmed, although a little bit, in the radial direction of the electrode, of the temperature on the electrode and the sheet resistance thereof, within a range around 1,000° C. Further, when the temperature is increased up to be equal to or higher than 1,200° C., i.e., being necessary for activation of SiC, it can be seen that the temperature on the outer peripheral portion of the electrode goes down comparing to that of a central portion of the electrode. It can be considered that a countermeasure should be taken to such generation of offset of the temperature distribution within the electrode surface, from a viewpoint of processing on the wafer of a large diameter, and the cause of reasons thereof is studied. As a result thereof, in exchanging heats under the temperature of 1,200° C. or higher than that, heat radiation comes to be dominant, and it can be considered that the temperature distribution is determined by distribution of heat input from the plasma, as well as, the heat radiation from the electrode heated, and also a balance of incoming and outgoing of the heat between a heat insulating material and/or a mirror surrounding it. According to the present invention, being accomplished upon basis of such knowledge, as mentioned above, there is provided the structure for restricting a region of producing the plasma by changing configuration of the electrode, and thereby enabling to control the distribution of heat input from the plasma. Also, on the outer peripheral portion of the electrode, there are provided heat-insulating plates, by plural numbers thereof, and thereby achieving the structure for reducing the heat radiation loss from the outer peripheral portion of the electrode. With those countermeasures, it is possible to provide a plasma heat treatment apparatus for enabling to suppress the deterioration of the distribution of temperature within the electrode surfaces, even in case where the offset of the distribution of temperature is generated within the wafer surface.

Hereinafter, the details thereof will be explained by referring to embodiments.

### First Embodiment

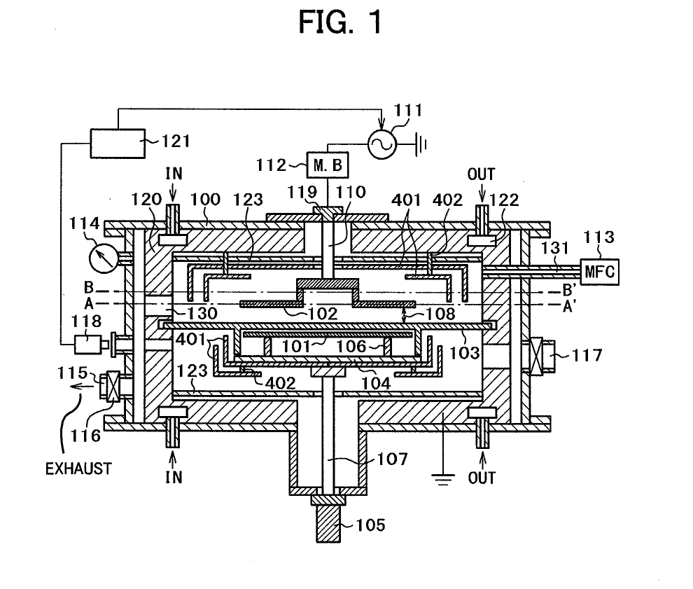

Explanation will be made about a first embodiment of the present invention, by referring to FIGS. 1 to 3. FIG. 1 is a cross-section view for showing the fundamental configuration of the plasma heat treatment apparatus according to the present embodiment. This plasma heat treatment apparatus comprises a heat treatment chamber 100 for heating a sample 101 to be heated (e.g., a body to be processed), indirectly, by a lower electrode 103, which is heated with using plasmas generating between an upper electrode 102 and the lower electrode 103.

The heat treatment chamber 100 comprises the ring-shaped upper electrode 102, being hollow at a central portion thereof, the lower electrode 103, i.e., a heating plate disposed opposing or facing to the upper electrode 102, a sample stage 104 having a support pin 106 for supporting the sample 101 to be heated thereon, a reflection mirror 120 for reflecting radiation heat thereupon, a radio-frequency power supply 111 for supplying radio-frequency electric power for use of production of the plasma to the upper electrode 102, a gas introducing means 113 for supplying a gas within the heat treatment chamber 100, and a vacuum valve 116 for adjusting the pressure within the heat treatment chamber 100. A reference numeral 117 denotes a loading/unloading port for the sample to be heated. However, in each figure, the same reference numerals depict the same constituent elements.

The sample 101 to be heated is supported on the support pin 106 of the sample stage 104, and is disposed below, in the vicinity of the lower electrode 103. Also, the lower electrode 103 is held by the reflection mirror 120, but not in contact with the sample 101 to be heated and the sample stage 104. In the present embodiment, as the sample 101 to be heated is applied a SiC substrate of 4 inches (φ 100 mm). Diameter and width of the upper electrode 102 and the sample stage 104 are determined to be 120 mm and 5 mm, respectively. Also, diameter of the hollow portion at the center of the upper electrode (i.e., inner diameter of the ring-shaped upper electrode) is determined to be 20 mm.

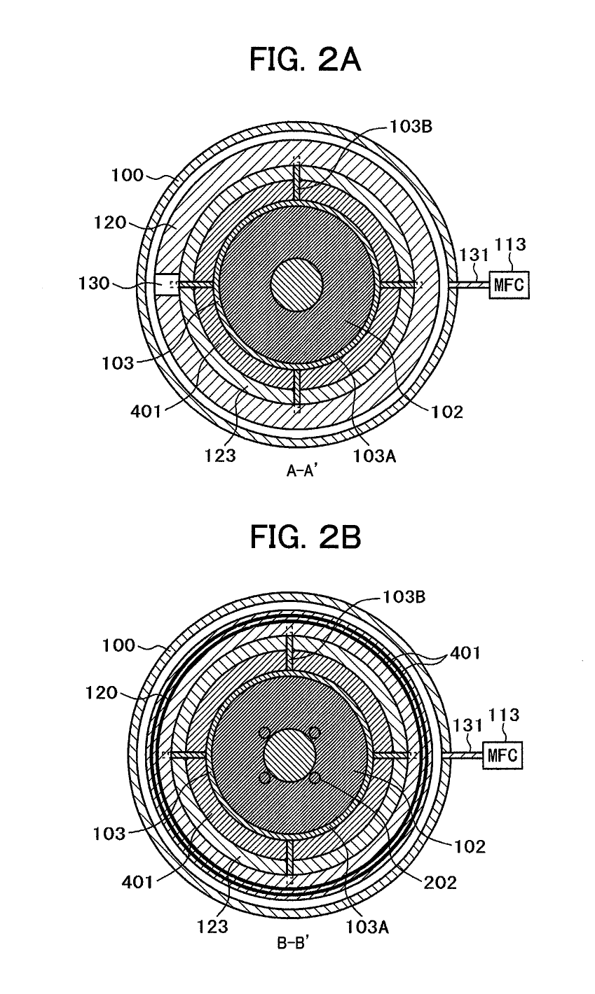

The upper electrode and the lower electrode will be explained by referring to FIGS. 2A and 2B. An upper plane view along A-A′ line in FIG. 1 is shown in FIG. 2A. The lower electrode 103 comprises a disc-shaped member 103A, and four (4) pieces of beams 103B, being disposed at an equal distance therebetween for connecting the disc-shaped member 103A and the reflection mirror 120. Thickness of the lower electrode 103 is determined to be 2 mm. However, the number, the area and the thickness of the beams 103B may be determined by taking strength of the lower electrode 103 and heat radiation from the lower electrode 103 to the reflection mirror 120 into the consideration thereof. Also, the lower electrode 103 covers a side surface of the sample 101 to be heated, and also has a member having an inner cylinder shape on an opposite side to the surface facing to the upper electrode 102.

An upper plane view along B-B′ line in FIG. 1 is shown in FIG. 2B. The upper electrode 102 is made up with the ring-shaped member mentioned above, and is supported by four (4) pieces of support rods 202, being disposed at an equal distance therebetween for connecting an upper feed wire 110. As a material of the supporting rod is applied graphite, because it is necessary to conduct the upper feed wire 110 and the upper electrode 102. A number of the support rods 202 and cross-section area thereof may be determined by the strength of the upper electrode 102, current from the upper feed wire 110 to the upper electrode 102, and heat radiation from the support rods 202 into the consideration thereof.

The lower electrode 103, because of the structure having such beams as shown in FIG. 2A, is able to suppress heat of the lower electrode 103, which is heated by the plasma, to transfer to the reflection mirror 120, comparing to the structure of contacting the periphery of the disc-shaped lower electrode 103 directly on the reflection mirror, and functions as a heating plate having high thermal efficiency. However, the plasma produced between the upper electrode 102 and the lower electrode 103 diffuses into a side of the vacuum valve 116, passing through spaces defined between the beams; however, because the sample 101 to be heated is covered by the member having the inner cylinder shape mentioned above, therefore there is no chance that the sample 101 to be heated is exposed to the plasma.

Also, the upper electrode 102, the lower electrode 103, the sample stage 104 and the support pin 106 are used, each of which is obtained by accumulating SiC on the surface of a graphite substrate through the chemical vapor development method (hereinafter, being called “CVD” method).

Also, a gap defined between the lower electrode 103 and the upper electrode 102 is determined to be 0.8 mm. However, the sample 101 to be heated has thickness of around 0.5 mm to 0.8 mm, and also circumferential corner portions of the upper electrode 102 and the lower electrode 103 facing to each other are machined to be in the form of a taper or a round shape, respectively. This is for the purpose of suppressing the plasma localization due to concentration of electric fields at the corner potions of the upper electrode 102 and the lower electrode 103, respectively.

The sample stage 104 is connected with an up/down mechanism 105 through a shaft 107, so that an operation of the up/down mechanism 105 enables delivery of the sample 101 to be heated, or proximity of the sample 101 to be heated close to the lower electrode 103. However, the details thereof will be mentioned later. Also, as a material of the shaft 107, an alumina member is applied.

To the upper electrode 102 is supplied radio-frequency electric power from the radio-frequency power supply 111 through the upper feed wire 110. In the present embodiment, 13.56 MHz is applied as the frequency of the radio-frequency power supply 111. The lower electrode 103 is conducting with the reflection mirror 120 through the beams. Further, the lower electrode 103 is grounded through the reflection mirror 120. The upper feed wire 110 is also made of graphite, being the constituent material of the upper electrode 102 and the lower electrode 103.

Between the radio-frequency power supply 111 and the upper electrode 102 is disposed a matching circuit (however, “M.B” in FIG. 1 is an abbreviation of “Matching Box”), and thereby building up such structure that the radio-frequency electric power from the radio-frequency power supply 111 can be supplied to the plasma formed between the upper electrode 102 and the lower electrode 103 at high efficiency. In the present embodiment, although the radio-frequency power supply 111 is connected with the upper electrode through the matching circuit, but may be also connected with the lower electrode, or only with the lower electrode.

Within the heat treatment chamber 100, the upper electrode 102, the lower electrode 103 and the sample stage 104 have such structures of being surrounded by the reflection mirror 120. The reflection mirror 120 is made up, by optically polishing an interior wall surface of a metal substrate, and plating or deposing gold thereon. Also, in the metal substrate of the reflection mirror 120 is formed a flow passage 122 for coolant; i.e., achieving the structure for enabling to keep the temperature of the reflection mirror at a constant by running a cooling water therein. With provision of the reflection mirror 120, since heat radiation can be reflected thereupon, coming from at least any one of the upper electrode 102, the lower electrode 103 and the sample stage 104 (and a heat shield, which will be mentioned later), then it is possible to suppress the heat radiation and to increase the thermal efficiency; however, in case where the temperature of the heat treatment is middle/low temperature, the reflection mirror can be omitted.

Also, between the upper electrode 102 and the lower electrode 103, and the reflection mirror 120 is disposed a protection quartz plate 123. The protection quartz plate 123 has a function of protecting a surface of the reflection mirror 120 from the material thereof emitting therefrom (i.e., sublimation of the graphite, etc.) generating from the upper electrode 102, the lower electrode 103 and the sample stage 104, which rise up to high temperature, being equal to or higher than 1,200° C., and also a function of preventing the possible contaminant emitting from the reflection mirror 120, from being mixed with the sample 101 to be heated.

Surrounding the upper electrode 102, the lower electrode 103 and the sample stage 104 is disposed a heat shield 401. The heat shield 401 is divided into an upper portion and a lower portion, and the heat shield 401 of the upper portion is fixed onto the reflection mirror 120 through a fixing part 402, while the heat shield of the lower part onto the sample stage 104.

Also, an outer peripheral portion of the heat shield 401 has a multi-layer structure, i.e., the structure for enabling to reduce radiation efficiency, effectively, much more, on the outer peripheral portion. A fixing part 402 for fixing an upper heat shield is made from a fine rod-shaped member of quartz or ceramic. A material of the fixing part 402 is selected one, to have heat conductivity as low as possible, and has the minimum size for fixing the heat shield 401, thereby achieving the structure for suppressing the heat transmission loss from the heat shield to the reflection mirror 120. Also, in FIG. 1, the heat shield 401 is formed from a tungsten foil having thickness of 0.1 mm.

The heat treatment chamber 100, in which the upper electrode 102 and the lower electrode 103 are disposed, has such structure that a gas can be introduced therein, up to 10 atmospheric pressures by the function of a gas introducing means 113 and a gas introduction nozzle 131. Monitoring is made on the pressure of the gas to be introduced, by a pressure detecting means 114. Also, the heat treatment chamber 100 is dischargeable of the gas therein, by a vacuum pump to be connected between an exhaust port 115 and a vacuum valve 116. It is preferable, for a tip of the gas introduction nozzle 131, to be disposed at the height between those of the upper electrode 102 and the lower electrode 103. The tip of the gas introduction nozzle 131 has a shape, being thin as it comes close the tip thereof, i.e., having such structure that the gas can blast into, energetically, between the electrodes. The position of the gas introduction nozzle 131 is variable. Also, for avoiding the electric discharge between the upper electrode 102 and the gas introduction nozzle 131, it is preferable to apply an insulating material for the gas introduction nozzle 131. In the present embodiment, alumina is applied into the gas introduction nozzle 131. Also, an internal exhaust port 130 is provided at the height between those of the upper electrode 102 and the lower electrode 103, so as to reduce conductance from a position between the upper/lower electrodes up to the internal exhaust port 130, thereby enabling the gas between those electrodes to be discharged, at high efficiency. With this, soot emitting from the respective electrodes can be discharged out, quickly, without staying within the heat treatment chamber 100. Also, the gas introduction nozzle 131 can suppress the gas introduced from flowing into a lower side of the lower electrode 103, if it is disposed above the beams of the lower electrode 103, and thereby enabling a gas to flow between the upper electrode 102 and the lower electrode 103, at high efficiency. However, the internal exhaust port 130 makes easy the replacement of the gas between the upper/lower electrodes, because it is disposed at the position facing to the gas introduction nozzle 131.

In the present embodiment, He is applied as the gas introduced into the heat treatment chamber 100. At the time when the gas pressure is stabilized in the heat treatment chamber 100, the radio-frequency electric power from the radio-frequency power supply 111 is supplied to the upper electrode 102 through the matching circuit 112 and a power introduction terminal 119, so as to produce the plasma within a gap 108, and thereby conducting the heating of the upper electrode 102 and the lower electrode 103. Energy of the radio-frequency electric power is absorbed into electrons within the plasma, and further due to collision of those electrons, atoms or molecules of the gas of the raw material are heated. Also, ions generated through ionization are accelerated by sheathes on surfaces of the upper electrode 102 and the lower electrode 103, in contact with the plasma, due a potential difference generated therebetween, and are incident (or hit) upon the upper electrode 102 and the lower electrode 103 while making collision on the particle of the material gas. Because of the process of this collision, it is possible to increase the temperature of the gas filled up between the upper electrode 102 and the lower electrode 103, and/or the temperature on surfaces of the upper electrode 102 and the lower electrode 103. However, during the time when heating, if stopping the introduction, or bringing an amount of that introduction down to zero (0), of the He gas into the heat treatment chamber 100, it is possible to heat the electrodes, further, up to the temperature higher than that, much more.

It can be considered that, in particular, in the vicinity of the atmospheric pressure, as was mentioned in the present invention, the material gas, being filled up between the upper electrode 102 and the lower electrode 103, can be heated, effectively, because the ions collide upon particles of the material gas, very frequently, when passing through the sheathes. As a result of this, temperatures of those electrodes rise up. When the temperatures of those electrodes rise up, then the loss due to the heat radiation, etc., is increased, and thereafter, finally balancing is achieved between the heat input to those electrodes and the heat loss from those electrodes, then the temperatures of those electrodes come to be saturated, approximately.

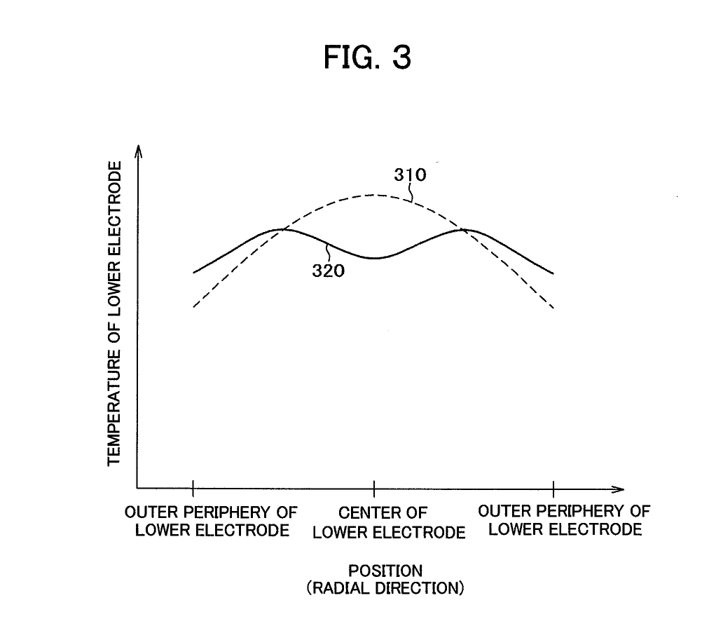

FIG. 3 shows temperature distribution 320 within a surface of the lower electrode when applying the upper electrode having the hollow in the central portion thereof (i.e., the ring-shaped upper electrode). With the temperature distribution 310 in case where the upper electrode and the lower electrode are configured to be equal in the area thereof (i.e., the configuration of the conventional upper electrode having a circular shape, but not shown in the figure), because the higher the temperature, the closer the distance to the center of a wafer, under the high temperature process equal to or higher than 1,200° C., then it is concerned that this comes up to be a problem in the future, if the wafer will be enlarged in the diameter thereof, or if demand will be made for further uniformity of the heat input. Even if the heat input is constant from the plasma into the electrodes, since the larger the heat radiation from the electrode, the closer the distance up to the outer periphery thereof, as a result thereof, the temperature on the peripheral portion thereof comes to be low in the temperature. On the contrary to this, in case where the upper electrode has a ring-like shape, strong electric field is generated between an outer periphery of the ring-shaped upper electrode 102 and the lower electrode 103, and therefore it is possible to produce the plasma. On the other hand, the electric field at the central portion of the lower electrode is week, then no plasma is generated, therefore it is possible to suppress the heating in the central portion of the lower electrode 103. Namely, with such structure of the electrodes according to the present embodiment as mentioned above, it is possible to form the plasma in a ring-like shape, and also possible to lower the temperature in the central portion thereof, but the temperature of which can rises up easily, at the most. Also, minimizing the area of the upper electrode reduces a region for plasma producing, and concentration of the electric power input to the outer periphery of the upper electrode increases; therefore, the temperature on the outer peripheral portion goes up. As a result of this, it is possible to reduce the temperature difference within the wafer surface, by lowering the temperature at the central portion of the wafer, while increasing the temperature up, on the outer periphery thereof (see temperature distribution 320). In particular, with determining ring inner diameter of the ring-shaped upper electrode, in such a manner that the temperature, at the central portion of the wafer lowered down, comes to be equal to the temperature, increased up on the outer peripheral portion, it is possible to increase the uniformity of the temperature distribution on the electrodes, much more. Forming the opening portion in the upper electrode enables to control the temperature distribution within the electrode surfaces. Thus, with provision of the opening portion in the upper electrode, although it is possible to control the temperature distribution within the electrode surfaces, but it is also preferable to determine the ring inner diameter to be equal to or greater than 10 mm φ, in case of the ring-shaped upper electrode, for example. This is because it is difficult to control the temperature, if the opening region is too narrow.

The temperature of the lower electrode 103 or the sample stage 104, during the time when the heat treatment is conducted on the sample to be heated, is measured by a radiation thermometer 118, and with using this measured value, since an output of the radio-frequency power supply 111 is so controlled by a control device 121 that it comes to a predetermined value, therefore it is possible to achieve the temperature control of the sample 101 to be heated at high accuracy. In the present embodiment, the radio-frequency electric power to be inputted is determined to 20 kW, at the maximum thereof.

In order to increase the temperatures of the upper electrode 102, the lower electrode 103 and the sample stage 104 (including the sample 101 to be heated) with high efficiency, there is necessity of suppression of heat transfer of the upper feed wire 110, heat transfer though an ambient atmosphere of the He gas and radiation (of a region from an infrared light up to a visible light) from high-temperature area. In particular, under the condition of high-temperature, an influence of the heat radiation is very large due to the radiation, then reduction of the radiation loss is essential for increasing the efficiency of heating. However, the radiation loss increases in an amount thereof, in proportion with 4th power of absolute temperature.

In the present embodiment, the gap 108 between the upper electrode 102 and the lower electrode 103 is determined to be 0.8 mm, but the similar effect can be obtained within a range from 0.1 mm to 2 mm. In case of the gap narrower than 0.1 mm, the electric discharge can be obtained therebetween, but there is necessity of functioning with high accuracy for maintaining degree of penalization between the upper electrode 102 and the lower electrode 103. Also, changing of quality of the surfaces of the upper electrode 102 and the lower electrode 103 (i.e., roughness, etc.) is undesirable, because it results to affect ill influences upon the plasma. On the other hand, the gas 108, exceeding 2 mm, because it lowers ignitability of the plasma and increases the radiation loss from the gap, as a problem, therefore it is also undesirable.

In the present embodiment, pressure within the heat treatment chamber 100 for producing the plasma therein is determined to be 0.1 air pressure; however, the similar operation can be made under the pressure equal to or less than 10 air pressures. In particular, a gas pressure, being equal to or higher than 0.01 air pressure and also being equal to or lower than 0.1 air pressure, is suitable. If it comes down to be equal to or lower than 0.001 air pressure, the frequency of collisions of the ions goes down, then the ions having large energy are incident (or hit) upon the electrodes, i.e., a concern or possibility is brought about that the electrode surface is spattered, or so on thereby. Also, in case where a range of the gap 108 between the upper electrode 102 and the lower electrode 103 lies from 0.1 mm to 2 mm, from a Paschen's law, voltage for maintaining the electric discharge goes up, and this is not preferable. On the other hand, if the pressure is equal to or higher than 10 air pressures, since a risk of generating an abnormal electric discharge (i.e., unstable plasma or electric discharge other than between the upper electrode and the lower electrode) come to be high, therefore is not preferable. Also, in the present embodiment, the gas pressure is controlled by changing an amount of gas flow; however, the similar effect can be obtained, through adjustment of the gas pressure by changing an amount of gas discharge. However, it is of course that the pressure control can be conducted by changing both the amount of gas flow and the amount of gas discharge, simultaneously.

In the present embodiment, He gas is applied as the material gas for use of producing the plasma; however, it is needless to say that the similar effect can be achieved by applying a gas mainly made of inactive gas, such as, Ar, Xe, Kr, etc., other than that. The He gas applied in the present embodiment is superior in the ignitability of plasma and the stability around the atmospheric pressure, but is high in heat conductivity of the gas; therefore, the heat loss due to heat transfer through an atmosphere of the gas is relatively large. On the other hand, the gases having large mass, such as, Ar, Xe, Kr, etc., are low in the heat conductivity thereof, and are advantageous from a viewpoint of the heat efficiency.

In the present embodiment, graphite is applied on opposing sides of the surfaces of the upper electrode 102, the lower electrode 103 and the sample stage 104, which are in contact with the plasma, obtained by coating of silicon carbonate thereon through CVD method, but the similar effect can be obtained by applying a single body of graphite, a member obtained by coating thermal crack carbonate on graphite, a member treated with a vitrification process on the surface of graphite, and SiC (crystalline, polycrystalline, monocrystal), other than that. It is needless to say that the graphite to be a substrate of the upper electrode 102 or the lower electrode 103, or the coating to be treated on the surface thereof, is preferable, to be as high as possible in purity thereof, from a viewpoint of preventing the sample 101 to be heated from being contaminated thereon. Further, it is also needless to say that the higher the heat conductivity, the more difficult the generation of the difference of temperature distribution within the surface, and therefore it is possible to make the difference small of temperature distribution on the sample to be heated.

Also, during the time when the temperature is high, there may be a case where the contamination upon the sample 101 to be heated is influenced from the upper feed wire 110. Therefore, in the present embodiment, also the graphite similar to the upper electrode 102 and the lower electrode 103 is also applied to the upper feed wire 110. Also, heat on the upper electrode 102 transfers onto the upper feed wire, and it results into the loss. Therefore, there is necessity of suppressing the heat transfer from the upper feed wire 110, down to the minimum, but as far as is necessary.

Therefore, it is necessary to make a cross-section area of the upper feed wire 110, which is made up from the graphite, as small as possible, while as long as possible in the length thereof. However, if making the cross-section area of the upper feed wire 110 is made small, extremely, while making the length thereof too long, loss of the radio-frequency electric power comes to be large, and this brings about lowering of a heating efficiency of the sample 101 to be heated. For this reason, in the present embodiment, the cross-section area of the upper feed wire formed from the graphite is determined to be 12 mm2 in the cross-section area and to be 40 mm in the length thereof, from the above viewpoints mentioned. The similar effect also can be obtained by the upper feed wire 110 within a region of the cross-section area from 5 mm2 to 30 mm2, and the length of the upper feed wire 110 from 30 mm to 100 mm.

Further, heat of the sample stage 104 transfers onto the shaft 107, and then comes to loss. Therefore, there is also necessity of suppressing the heat transfer from the shaft 107 down to the minimum, but as far as is necessary, similar to the upper feed wire 110 mentioned above. Therefore, it is necessary to make the cross-section area of the shaft 107, which is made of a material of alumina, as small as possible, while making the length thereof long. In the present embodiment, by taking the strength thereof, etc., into the consideration, the cross-section area and the length of the shaft 107 made of the alumina material are made similar to those of the upper feed wire 110 mentioned above.

In the present embodiment, tungsten is applied as a material of the heat shield 401; however, it is also possible to apply other material(s) therefor, if having a high melting point and a low radiating power, and also the similar effect can be obtained by applying one other than that, being made of WC (tungsten carbonate), MoC (molybdenum carbonate), Ta (tantalum), Mo (molybdenum), or that obtained by coating TaC (tantalum carbonate) on a graphite substrate, for example. Also, in the similar manner, tungsten having thickness of 0.1 mm is applied for the heat shield 401, but the similar effect can be obtained by applying a material having the thickness equal to or lower than 1 mm. The material thicker than 1 mm comes to be relatively large, in an increase of the heat capacity thereof, as well as, an increase the cost thereof, therefore is undesirable.

In the present embodiment, the radio-frequency power supply of 13.5 MHz is applied as the radio-frequency power supply 111 for use of producing the plasma; however, this is because 13.56 MHz is an industrial frequency and therefore that power supply is available with a low cost, and also a standard of radio wave leakage thereof is low; i.e, the cost of the apparatus can be reduced down. However, it is needless to say that, principally, the heat treatment can be made through the same principle, with other frequencies. In particular, the frequency equal to or higher than 1 MHz, and further equal to or lower than 100 MHz is suitable. If the frequency is lower than 1 MHz, the radio-frequency voltage must be high when supplying the electric power necessary for heat treatment, and then the abnormal electric discharge (i.e., unstable plasma or electric discharge other than between the upper electrode and the lower electrode) is generated, and it is difficult to produce the stable plasma. Also, with the frequency exceeding 100 MHz, impedance in the gap 108 defined between the upper electrode 102 and the lower electrode 103 comes to be low, then it is difficult to obtain the voltage necessary for producing the plasma, and therefore not preferable.

With the embodiment mentioned above, it is possible to provide the plasma heat treatment apparatus for enabling a control of the of the distribution of temperature within the electrode surfaces, without increasing the electric power to be inputted, even when heating is made on the sample to be heated having the large diameter with using the plasma. With this, it is possible to improve the distribution of temperature within the surface, without lowering the efficiency of heating.

### Second Embodiment

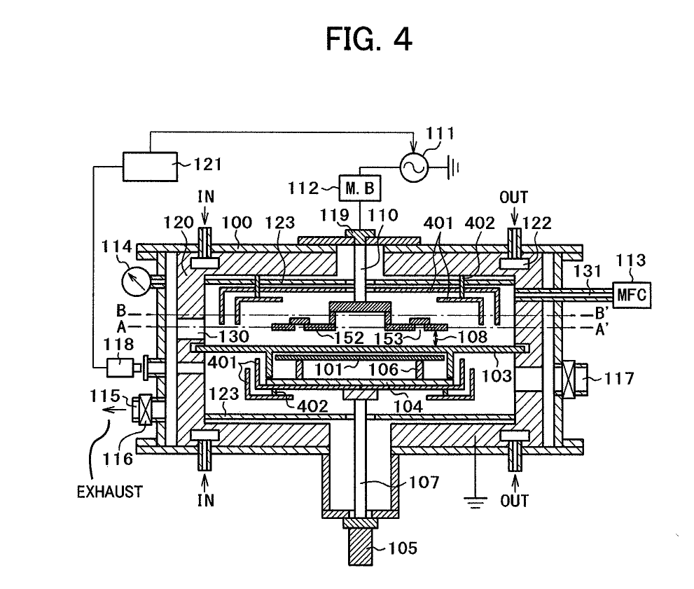

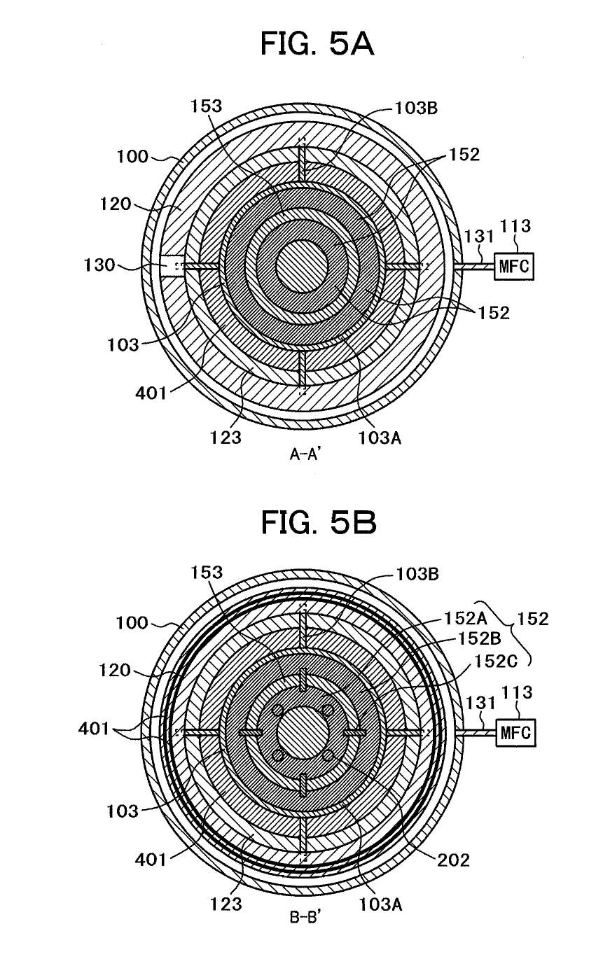

Explanation will be given on a second embodiment according to the present invention by referring to FIGS. 4 to 6. However, the matter(s), being described in the first embodiment but not described in the present embodiment, is/are also applicable into the present embodiment, if there is no special reason(s) of not. FIG. 4 is a cross-section view for showing the fundamental configuration of the plasma heat treatment apparatus according to the present embodiment, and FIGS. 5A and 5B show the upper electrode and the lower electrode according to the present embodiment, respectively. About the upper electrode will be given the explanation by referring to is. 5A and 5B. Upper plane views along A-A′ line and B-B′ line in FIG. 4 are in FIGS. 5A and 5B. A divided ring-shaped upper electrode (i.e., a double ring upper electrode) 152 comprises a first ring-shaped member 152A, a second ring-shaped member 152B, and beams 152C for connecting the first ring-shaped member 152A and the second ring-shaped member 152B mentioned above. The upper feed wire 110 and the first ring-shaped member 152 mentioned above are connected with through four (4) pieces of support rods 202. For the support rods 202 and the beams 152C mentioned above, because of necessity of conducting between the first ring-shaped member 152A and the second ring-shaped member 152B, graphite is applied. A number and a cross-section area of support rods 202 and the beams 152C mentioned above may be determined, by taking the strength of the divided ring-shaped upper electrode 152, current flowing from the upper feed wire 110 to the divided ring-shaped upper electrode 152 mentioned above, and hear radiation from the support rods 202 and the beams 152C mentioned above into the consideration thereof.

Comparing to the case of applying such structure therein, i.e., the upper electrode and the lower electrode are equal to in an area thereof (i.e., the conventional structure, not shown in the figure), in the embodiment 1, the difference of temperature within surface can be reduced, with adoption of the ring-shaped upper electrode 102. However, even in the case of taking the countermeasure of the embodiment 1, if the difference of temperature within surface is larger than a desired region, there may be necessity of further making the difference of temperature smaller than that. Difference between the upper electrode shown in FIGS. 5A and 5B and that shown in FIGS. 2A and 2B of the embodiment 1 lies in that the ring-shaped upper electrode 102 is divided into an inner side and an outer side, and the gap 153 is provided between them (i.e., the double ring structure). A strong electric field is generated between the first ring-shaped member 152A and the second ring-shaped member 152B and the lower electrode 103, therefore it is possible to generate plasma. On the other hand, the electric field comes to be weak between the gap 153 defined between the first ring-shaped member 152A and the second ring-shaped member 152B and the lower electrode 103, and therefore the heat input from the plasma is reduced. Also, because of an increase of an amount of heat passing due to the heat radiation from the lower electrode surface opposing to the gap 153 towards to the gap 153 mentioned above, temperature of the portions opposing to the gap 153 goes down. However, the heat radiation from the lower electrode passing through the gap 153 mentioned above, because of being shielded by the heat shield 401, will not lose a heating efficiency of the system as a whole. Thus, under the heat distribution of the lower electrode, with forming the gap in the upper electrode opposing to the portion, which will be high in the temperature thereof, it is possible to lower the temperature selectively, without losing the heating efficiency of the system as a whole, and thereby leveling the temperature distribution within the surface of the lower electrode.

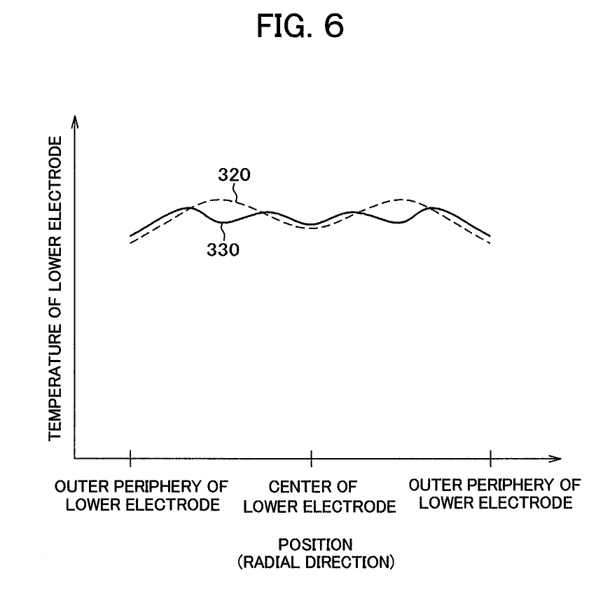

FIG. 6 shows the temperature distribution 330 within the surface of the lower electrode in case when applying the divided ring-shaped upper electrode 152. Comparing to such temperature distribution 320 as was shown in the first embodiment, i.e., a middle between a center of the lower electrode and an outer periphery of the lower electrode is high in temperature, if there is the gap 153 of the divided ring-shaped upper electrode 152 at the position opposing to the high temperature portion of the lower electrode, as is shown in the second embodiment, then the temperature of that can be lowered down (see the heat distribution 330). Also, similar to the case of the first embodiment, because of reduction of the area of the upper electrode, the region for producing the plasma is reduced, and the concentration of the electric power inputted to the outer peripheral portion of the upper electrode is increased, therefore the temperature on the outer periphery goes up. Also, by means of the heat shield 401, the heat radiation passing through the gap 153 of the upper electrode can be prevented from being lost as the heat loss of the system as a whole. As a result of this, it is possible to lower the temperature of the high temperature portion(s) on the lower electrode, without accompanying the heat loss of the system as a whole, and also to level or unify the temperature distribution within the surface of the lower electrode.

In the present embodiment, the gap is provided by applying the ring-shaped electrode divided into two (2), but in case where the heat distribution on the lower electrode is insufficient or not enough, an improvement can be achieved on the temperature distribution of the lower electrode by further dividing the electrode so as to increase the number of the gaps. However, although no electrode member is disposed at the central portion of the upper electrode in the present embodiment, but such an electrode member can be also disposed. With this, it is possible to suppress the temperature from being lowered down too much in the central portion.

In the present embodiment, the upper electrode is built up, with provision of the gap 153 by combining plural numbers of the ring-shaped members 152A and 152B; however, it is needless to say that the similar effect can be obtained by applying the upper electrode having plural numbers of ring portions, which is defined by a groove corresponding to the gap 153 on one piece of a member. Further, in the case of machining the one piece of the member, it is possible to heighten an accuracy of position of the opening portion, comparing to the case of combining the plural numbers of the members. However, in the case of combining the plural numbers of the members, it is possible to combine the members of materials differing from each other. Also, it is possible to make the number of the rings three or more than that. And, by combining the members each having a desired shape, or forming an opening of a desired shape in one piece of member, it is possible to control the temperature distribution into a desired one within the electrode surface.

As was mentioned above, according to the present embodiment, it is possible to provide the plasma heat treatment apparatus for enabling to lower the temperature of the high temperature portion(s) on the lower electrode, and thereby being able to obtain an improvement within the surface of the lower electrode. Also, it is possible to provide the plasma heat treatment apparatus being able to control the temperature distribution within the electrode surface(s).

However, the present invention should not be limited to the embodiments mentioned in the above, but it may include various variations thereof. For example, the embodiments mentioned above are explained in the details thereof, for the purpose of explaining the present invention, in a easily understandable manner; but the present invention should not always be limited to that having all of the constituent elements thereof, which are explained. Or, a part(s) of the constituent element(s) of a certain embodiment can be substituted by that/those of other embodiment, or to the constituent element(s) of a certain embodiment can be added to that/those of the other embodiment, Also, a part(s) of the constituent elements of each added/deleted/replaced by other constituent element(s).

What is claimed is:

1. A plasma heat treatment apparatus, comprising:
a treatment chamber, which is configured to heat a sample to be treated therein;
a first electrode, which is disposed within the treatment chamber;
a plate-shaped second electrode, which is disposed opposing to the first electrode; and
a radio-frequency power supply, which is configured to supply radio-frequency electric power to the first electrode or the second electrode; and
a gas supplying means, which is configured to supply a gas within the treatment chamber,
wherein the first electrode has an opening portion therein.

2. The plasma heat treatment apparatus according to claim 1, wherein the opening portion is provided for limiting a region for producing plasma therein.

3. The plasma heat treatment apparatus according to claim 1, wherein the opening portion has a circular shape, and is provide in a central portion of the first electrode.

4. The plasma heat treatment apparatus according to claim 1, wherein the opening portion is provided in a manner of a ring, surrounding a central portion of the first electrode.

5. The plasma heat treatment apparatus according to claim 4, wherein the opening portion has a circular second opening portion, further, in an inside of the ring-shaped first opening portion.

6. The plasma heat treatment apparatus according to claim 4, wherein the opening portion further has plural numbers of ring-shaped opening portions surrounding the ring-shaped opening portion.

7. The plasma heat treatment apparatus according to claim 1, wherein the first electrode is configured by combining plural numbers of members.

8. The plasma heat treatment apparatus according to claim 1, wherein the first electrode is made from one piece of member, in which the opening portion is formed.

9. The plasma heat treatment apparatus according to claim 1, wherein the radio-frequency power supply is provided for supplying radio-frequency electric power to the first electrode.

10. A plasma heat treatment apparatus, comprising:
a treatment chamber, which is configured to heat a sample to be treated therein;
a first electrode, which is disposed within the treatment chamber;
a second electrode opposing to the first electrode;
a radio-frequency power supply, which is configured to supply radio-frequency electric power to the first electrode or the second electrode;
a gas supplying means, which is configured to supply a gas within the treatment chamber; and
a heat radiation suppressing member, which is provided for suppressing heat radiation, wherein
the heat radiation suppressing member comprises a first heat radiation suppressing member and a second heat radiation suppressing member,
the first heat radiation suppressing member is disposed to surround the first electrode and the second electrode, for reflecting the heat radiation thereupon, and
the second heat radiation suppressing member includes members exhibiting a high melting point and a low radiation factor therein, being disposed between the first electrode and the first heat radiation suppressing member, and between the second electrode and the first heat radiation suppressing member, respectively, in a form of multiple-layers thereof.

11. The plasma heat treatment apparatus according to claim 10, wherein the first heat radiation suppressing member is for suppressing heat radiation from at least either the first electrode or the second electrode, and also heat radiation from the second heat radiation suppressing member.

12. The plasma heat treatment apparatus according to claim 10, wherein the second heat radiation suppressing member has an opening portion.

13. The plasma heat treatment apparatus according to claim 1, further comprising
a heat radiation suppressing member for suppressing the heat radiation,
wherein the heat radiation suppressing member comprises a first heat radiation suppressing member and a second heat radiation suppressing member,
the first heat radiation suppressing member is disposed to surround the first electrode and the second electrode, for reflecting the heat radiation thereupon, and
the second heat radiation suppressing member includes members exhibiting a high melting point and a low radiation factor therein, being disposed between the first electrode and the first heat radiation suppressing member, and between the second electrode and the first heat radiation suppressing member, respectively, in a form of multiple-layers thereof.

14. The plasma heat treatment apparatus according to claim 13,
wherein the first heat radiation suppressing member is for suppressing heat radiation from at least either the first electrode or the second electrode, and also heat radiation from the second heat radiation suppressing member.

15. The plasma heat treatment apparatus according to claim 13, wherein the second heat radiation suppressing member has an opening portion.
